(19) United States
(12) Patent Application Publication
(10) Pub. No.: US 2022/0232738 A1
(43) Pub. Date: Jul. 21, 2022

(54) REFRIGERANT VAPOR ADSORPTION FROM TWO PHASE IMMERSION COOLING SYSTEM

(71) Applicant: 3M INNOVATIVE PROPERTIES COMPANY, St. Paul, MN (US)

(72) Inventors: Phillip E. Tuma, Faribault, MN (US); Kevin A. Frankel, Woodbury, MN (US); Olaf C. Moberg, New Brighton, MN (US)

(21) Appl. No.: 17/609,608

(22) PCT Filed: Apr. 28, 2020
(86) PCT No.: PCT/IB2020/053988

§ 371 Date: Nov. 8, 2021

Related U.S. Application Data
(60) Provisional application No. 62/844,985, filed on May 8, 2019.

(51) Int. Cl. H05K 7/20

(52) U.S. Cl. CPC H05K 7/20363; H05K 7/20327; H05K 7/20381; H05K 7/203

(57) ABSTRACT

A thermal management system includes a housing having an interior space; a heat-generating component disposed within the interior space; and a working fluid disposed within the interior space such that the heat-generating component contacts a liquid phase of the working fluid; and an adsorber assembly disposed within the interior space. The adsorber assembly is in fluid communication with the interior space and an environment external to the thermal management system. The adsorber assembly is configured to: (i) receive a fluid stream from the interior space, the fluid stream including a vapor phase of the working fluid and a non-condensable gas; (ii) at least partially separate the working fluid from the fluid stream and, then, vent the fluid stream to the environment external to the fluid space; and (iii) return the separated working fluid to the interior space.

### FIELD

The present disclosure relates to systems and methods for selectively removing fluids from 2-phase thermal management systems

### SUMMARY

In some embodiments, a thermal management system is provided. The thermal management system includes a housing having an interior space; a heat-generating component disposed within the interior space; and a working fluid disposed within the interior space such that the heat-generating component contacts a liquid phase of the working fluid; and an adsorber assembly disposed within the interior space. The adsorber assembly is in fluid communication with the interior space and an environment external to the thermal management system. The adsorber assembly is configured to: (i) receive a fluid stream from the interior space, the fluid stream including a vapor phase of the working fluid and a non-condensable gas; (ii) at least partially separate the working fluid from the fluid stream and, then, vent the fluid stream to the environment external to the fluid space; and (iii) return the separated working fluid to the interior space.

The above summary of the present disclosure is not intended to describe each embodiment of the present disclosure. The details of one or more embodiments of the disclosure are also set forth in the description below. Other features, objects, and advantages of the disclosure will be apparent from the description and from the claims.

### BRIEF DESCRIPTION OF THE FIGURES

FIG. 1 is a schematic of a two-phase immersion cooling system according to some embodiments of the present disclosure.

FIGS. 2A and 2B are schematic representations of an adsorber assembly in accordance with some embodiments of the present disclosure.

FIGS. 3A-3C are schematic representations of an adsorber assembly in accordance with some embodiments of the present disclosure.

### DETAILED DESCRIPTION

Large scale computer server systems can perform significant workloads and generate a large amount of heat during their operation. A significant portion of the heat is generated by the operation of the server systems. Due in part to the large amount of heat generated, these servers are typically rack mounted and air-cooled via internal fans and/or fans attached to the back of the rack or elsewhere within the server ecosystem. As the need for access to greater and greater processing and storage resources continues to expand, the density of server systems (i.e., the amount of processing power and/or storage placed on a single server, the number of servers placed in a single rack, and/or the number of servers and or racks deployed on a single server farm), continue to increase. With the desire for increasing processing or storage density in these server systems, the thermal challenges that result remain a significant obstacle. Conventional cooling systems (e.g., fan based) require large amounts of power, and the cost of power required to drive such systems increases exponentially with the increase in server densities. Consequently, there exists a need for efficient, low power usage systems for cooling the servers, while allowing for the desired increased processing and/or storage densities of the server systems.

Two-phase immersion cooling is an emerging cooling technology for the high-performance server computing market which relies on the heat absorbed in the process of vaporizing a liquid (the cooling fluid) to a gas (i.e., the heat of vaporization). The working fluids used in this application must meet certain requirements to be viable in the application. For example, the boiling temperature during operation should be in a range between for example 30° C.-75° C. Generally, this range accommodates maintaining the server components at a sufficiently cool temperature while allowing heat to be dissipated efficiently to an ultimate heat sink (e.g., outside air). The working fluid must be inert so that it is compatible with the materials of construction and the electrical components. Certain perfluorinated and partially fluorinated materials meet these requirements.

In a typical two-phase immersion cooling system, servers are submerged in a bath of working fluid (having a boiling temperature T_{b}) that is sealed and maintained at or near atmospheric pressure. A vapor condenser integrated into the tank is cooled by water at temperature T_{w}. During operation, after steady reflux is established, the working fluid vapor generated by the boiling working fluid forms a discrete vapor level as it is condensed back into the liquid state. Above this layer is the “headspace,” a mixture of a non-condensable gas (typically air), water vapor, and the working fluid vapor which is at a temperature somewhere between T_{w} and the temperature of ambient air outside the tank, T_{amb}. These 3 distinct phases (liquid, vapor, and headspace) occupy volumes within the tank.

During normal operation of 2-phase immersion cooling systems, the “headspace” phase must be occasionally vented. Such venting results in loss of working fluid vapor which is an undesirable operating cost. While compressing and/or cooling this vent stream are viable means for reducing the amount of working fluid vapor in the exiting stream, absent significant cost and complexity increases, such a mechanism removes only a fraction of the working fluid vapor. Consequently, simple and relatively low-cost devices, systems, and methods for capture and reclamation of the working fluid vapor from the headspace vent stream are desirable.

As used herein, “fluoro-” (for example, in reference to a group or moiety, such as in the case of “fluoroalkylene” or “fluoroalkyl” or “fluorocarbon”) or “fluorinated” means (i) partially fluorinated such that there is at least one carbon-bonded hydrogen atom, or (ii) perfluorinated.

As used herein, “perfluoro-” (for example, in reference to a group or moiety, such as in the case of “perfluoroalkylene” or “perfluoroalkyl” or “perfluorocarbon”) or “perfluorinated” means completely fluorinated such that, except as may be otherwise indicated, any carbon-bonded hydrogens are replaced by fluorine atoms.

As used herein, “halogenated material” means an organic compound that is at least partially halogenated (up to completely halogenated) such that there is at least one carbon-bonded halogen atom.

As used herein, “selective removal” refers to at least partial removal (up to total removal) of one or more particular fluid components (but less than all fluid components) from a sealed volume that includes two or more fluid components.

As used herein, “fluid” refers to the liquid phase and/or the vapor phase.

As used herein, the singular forms “a”, “an”, and “the” include plural referents unless the content clearly dictates otherwise. As used in this specification and the appended embodiments, the term “or” is generally employed in its sense including “and/or” unless the content clearly dictates otherwise.

As used herein, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

Generally, the present disclosure is directed to immersion cooling systems that provide for capture and reclamation of working fluid vapor that is present in a system vent stream comprising a vapor phase of a working fluid and either or both of a non-condensable gas or water vapor. In some embodiments, the immersion cooling systems may operate as two-phase vaporization-condensation systems for cooling one or more heat generating components. During normal operation, the vent stream may be routed to an adsorber that at least partially separates the working fluid from the fluid stream and, then, vents the remaining components of the fluid stream to the environment external to the immersion cooling system. The system may also be configured to desorb the separated working fluid from the adsorber and return the separated working fluid to a fluid reservoir within the system.

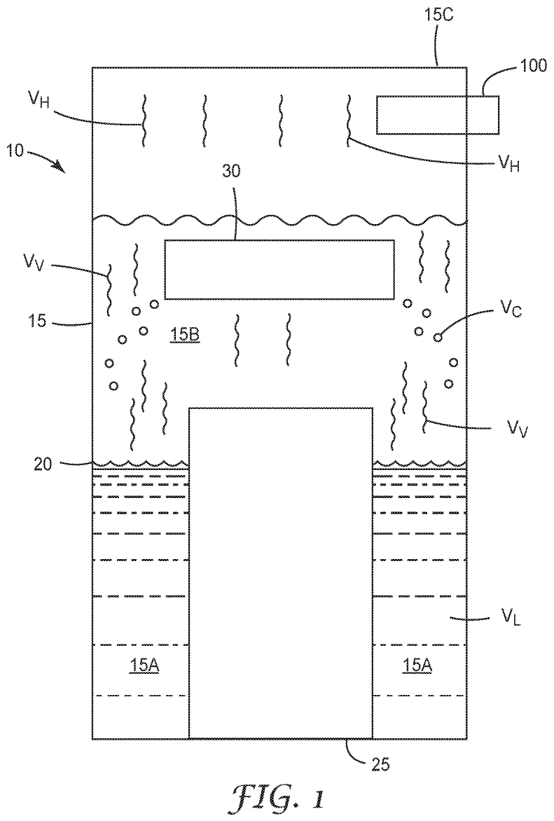

Referring now to FIG. 1, in some embodiments, a two-phase immersion cooling system 10 may include a housing 15 having an interior space. Within a lower volume 15A of the interior space, a liquid phase V_{L} of a working fluid having an upper liquid surface 20 (i.e., the topmost level of the liquid phase V_{L}) may be disposed. The interior space may also include an upper volume 15B extending from the liquid surface 20 to an upper wall 15C of the housing 15. During steady state operation of the system 10, the upper volume 15B may include a vapor phase V_{V} of the working liquid (generated by the boiling working fluid and forming a discrete phase as it is condensed back into the liquid state) and a headspace phase V_{H} including a mixture of non-condensable gas (e.g., air) and working fluid vapor, which is disposed above the vapor phase V_{V}.

In some embodiments, a heat generating component 25 may be disposed within the interior space such that it is at least partially immersed (up to fully immersed) in the liquid phase V_{L} of the working fluid. That is, while heat generating component 25 is illustrated as being only partially submerged below the upper liquid surface 20, in some embodiments, the heat generating component 25 may be fully disposed below the liquid surface 20. In some embodiments, the heat generating components may include one or more electronic devices, such as computing servers.

In various embodiments, a heat exchanger 30 (e.g., a condenser) may be disposed within the upper volume 15B. Generally, the heat exchanger 30 may be configured such that it is able to condense the vapor phase V_{V} of the working fluid that is generated as a result of the heat that is produced by the heat generating element 25. For example, the heat exchanger 30 may have an external surface that is maintained at a temperature that is lower than the condensation temperature of the vapor phase V_{V} of the working fluid. In this regard, at the heat exchanger 30, a rising vapor phase V_{V} of the working fluid may be condensed back to liquid phase or condensate V_{C} by releasing latent heat to the heat exchanger 30 as the rising vapor phase V_{V} comes into contact with the heat exchanger 30. The resulting condensate V_{C} may then be returned back to the liquid phase V_{L} disposed in the lower volume of 15 A.

In some embodiments, the system 10 may further include an adsorber assembly 100 disposed within the housing 15. The adsorber assembly 100 may be provided in fluid communication with the headspace phase V_{H} and the environment surrounding the system 10 such that the headspace phase V_{H} may be vented to the external environment surrounding the system 10 via the adsorber assembly 100.

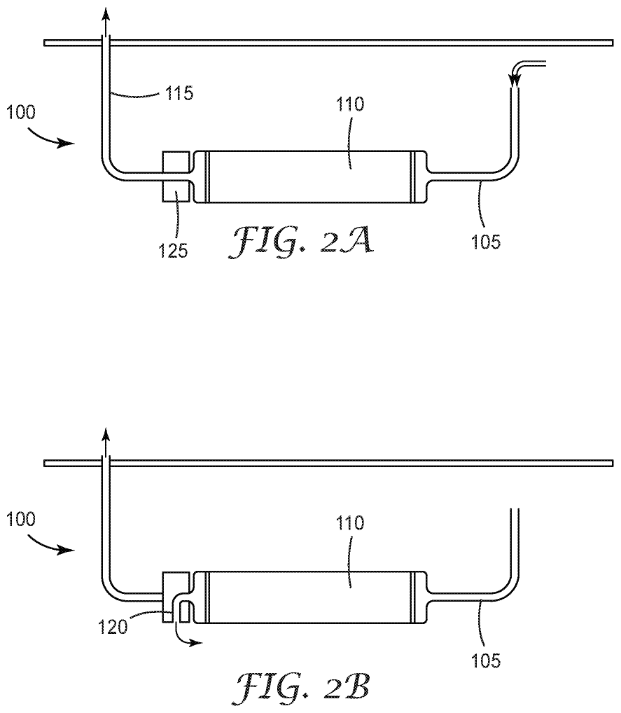

Referring now to FIGS. 2A and 2B, in some embodiments, the adsorber assembly 100 may include a fluid inlet 105, an adsorbent filter 110 disposed downstream of the first fluid inlet 105, a first fluid outlet 115, and a second fluid outlet 120, each of the first and second fluid outlets 115, 120 being disposed downstream of the adsorbent filter 110. The adsorber assembly 100 may further include a valve mechanism 125 configured to direct fluid downstream of the adsorbent filter 110 to either the first fluid outlet 115 or the second fluid outlet 120. In some embodiments, the first fluid outlet 115 may be in fluid communication with the external environment surrounding the system 10 and the second fluid outlet 120 may be in fluid communication with the interior space of the housing 15.

Regarding a driving force for the transport of the headspace phase V_{H} through the filter 110, in some embodiments, the system may be configured such that if the pressure in the interior space of the housing 15 should rise above a predetermined set point (indicating a need to release some portion of the headspace phase V_{H}), the valve mechanism 125 may be configured to actuate such that the headspace phase, V_{H}, is permitted to exit the interior space of the housing 15 by passing through fluid inlet 105, adsorbent filter 110 and fluid outlet 115.

In some embodiments, the adsorber assembly 100 may further include a desorption mechanism (not shown) that is operably coupled to the adsorbent filter 110 and configured to induce desorption of fluid that has been captured by the adsorbent filter 110. In some embodiments, the desorption mechanism may include a heating element that is configured to provide heat to the adsorbent filter's 110 filter media in an amount sufficient to cause desorption of fluid that has been captured by the adsorbent filter 110. For example, suitable heating elements may include electrical resistance heaters or a source of electrical current that is configured to pass the current through the filter media, thereby causing heating of the filter media. Alternatively, or additionally, the desorption mechanism may include a vacuum device coupled to the adsorbent filter 110 such that a vacuum condition may be induced within a chamber housing the filter media of the adsorbent filter 110. Such vacuum condition may, in turn, cause fluid captured by the filter media to desorb from the filter media.

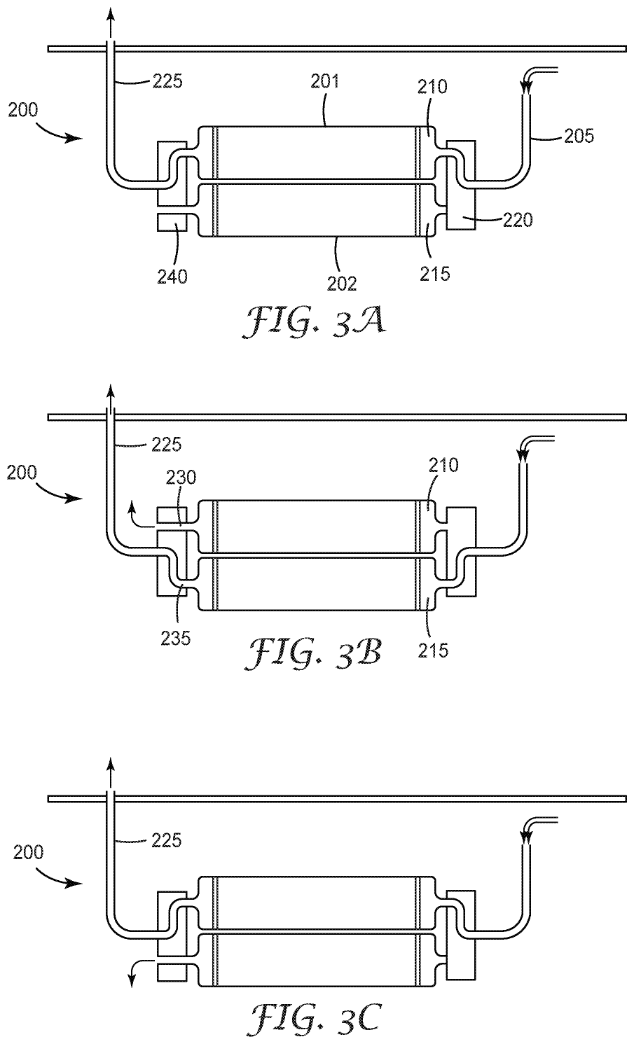

Referring now to FIGS. 3A, 3B, and 3C, an adsorber assembly 200 in accordance with some embodiments of the present disclosure is shown. As shown, as opposed to a single adsorbent filter, the adsorber assembly 200 may include a first adsorbent filter 201 and a second adsorbent filter 202. In this regard, the adsorber assembly 200 may be described as having first and second adsorption paths that may alternately couple the vent stream to the respective first and second adsorbent filters 201, 202. It is to be appreciated that configuration of the adsorber assembly 200 in this fashion facilitates continuous venting of, and adsorption of the working fluid vapor from, the vent stream. This is in contrast to the adsorber assembly 100, which design would require that the vent stream be interrupted during a desorption cycle.

In some embodiments, the adsorber assembly 200 may include a fluid inlet 205, a first filter inlet 210, a second filter inlet 215, and a first valve mechanism 220 configured to route fluid from the fluid inlet 205 to the first filter inlet 210 or the second filter inlet 215 (that is, depending on the position of first valve mechanism 220, the fluid inlet 205 may be in fluid communication with the first filter inlet 210 or the second filter inlet 215). The first and second adsorbent filters 201, 202 may be in fluid communication with and disposed downstream of the first and second filter inlet 210, 215, respectively. The fluid inlet 205 may be in fluid communication with the headspace phase V_{H} of the system 10 such that the headspace phase V_{H} may be routed to the adsorbent filters via the fluid inlet 205.

In some embodiments, the adsorber assembly 200 may further include a fluid outlet 225, a first filter outlet 230, a second filter outlet 235, and a second valve mechanism 240 configured to route fluid from the first and second filter outlets 230, 235 to either the fluid outlet 225 or the interior space of the housing 15 (that is, depending on the positioning of the second valve mechanism 240, the first and second filter outlets 230, 235 may be in fluid communication with either the fluid outlet 225 or the interior space of the housing 15). The first and second filter outlets 230, 235 may be in fluid communication with and disposed downstream of the first and second adsorbent filters 201, respectively. The fluid outlet 225 may be in fluid communication with the external environment surrounding the system 10.

As with the previous embodiments, the adsorber assembly 200 may further include a desorption mechanism (not shown) operably coupled to either or both of the first and second adsorbent filters 201, 202 and configured to induce desorption of fluid that has been captured by the adsorbent filters 201, 202.

In some embodiments, during a desorption cycle induced by heating, the captured fluid may leave the adsorbent as a partially saturated, saturated, or superheated vapor stream and enter the interior volume 15 to be condensed by the condenser 30. In some embodiments, during a desorption cycle induced by vacuum, the fluid may leave the adsorbent at a reduced pressure as a saturated or near saturated vapor stream to be ejected by the vacuum device and captured by the primary condenser 30.

In any of the above-described embodiments, the system may further include one or more sensors disposed in the flow path of the vent stream and configured to sense system parameters. For example, the system may include one or more sensors downstream of the adsorbent filters that are configured to detect the presence of a particular fluid (e.g., the working fluid). In this manner, the system may detect when the adsorbent filter no longer has capacity to adsorb the particular fluid. In response to such a detection, the system may initiate a desorption cycle that includes desorption of the fluid from the filter media and subsequent routing of the desorbed fluid to the interior space of the housing (or some other fluid reservoir). In this regard, the system may further include a programmable controller that is coupled to the any or all of the sensors, the valve mechanisms, and the desorption mechanisms for controlling the desorption cycles and flow paths of the vent stream in response to the sensed system parameters.

As previously discussed, in any of the above described embodiments, the adsorbent filters may be configured to selectively remove/capture one or more first fluids (e.g., the working fluid) from the vent stream while permitting the passage and venting of one or more second fluids (e.g., air) to the external environment surrounding the system 10 and, subsequently, allow for desorption of the captured fluid. In some embodiments, the adsorbent filters may include a porous media that allows for adsorption and desorption of the working fluid. The porous media may include both micro and mesopores to perform the adsorption and desorption operations. In some embodiments, the porous media may be be inert with respect to the working fluid (i.e, the working fluid does not change properties due to being adsorbed and desorbed by the porous media). In some embodiments, the adsorbent filters may include activated carbon beds. Alternatively, or additionally, any other suitable adsorbent filter may be employed, such as zeolites, silica, or silica gel filters.

In some embodiments, the working fluid may be or include one or more halogenated fluids (e.g., fluorinated or chlorinated). For example, the working fluid may be a fluorinated organic fluid. Suitable fluorinated organic fluids may include hydrofluoroethers, fluoroketones (or perfluoroketones), hydrofluoroolefins, perfluorocarbons (e.g., perfluorohexane), perfluoromethyl morpholine, or combinations thereof.

In some embodiments, in addition to the halogenated fluids, the working fluids may include (individually or in any combination): ethers, alkanes, perfluoroalkenes, alkenes, haloalkenes, perfluorocarbons, perfluorinated tertiary amines, perfluoroethers, cycloalkanes, esters, perfluoroketones, ketones, oxiranes, aromatics, siloxanes, hydrochlorocarbons, hydrochlorofluorocarbons, hydrofluorocarbons, hydrofluoroolefins, hydrochloroolefins, hydrochlorofluoroolefins, hydrofluoroethers, or mixtures thereof based on the total weight of the working fluid; or alkanes, perfluoroalkenes, haloalkenes, perfluorocarbons, perfluorinated tertiary amines, perfluoroethers, cycloalkanes, perfluoroketones, aromatics, siloxanes, hydrochlorocarbons, hydrochlorofluorocarbons, hydrofluorocarbons, hydrofluoroolefins, hydrochlorofluoroolefins, hydrofluoroethers, or mixtures thereof, based on the total weight of the working fluid. Such additional components can be chosen to modify or enhance the properties of a composition for a particular use.

In some embodiments, the working fluids of the present disclosure may have a boiling point during operation (e.g., pressures of between 0.9 atm and 1.1 atm or 0.5 atm and 1.5 atm) of between 30-75° C., or 35-75° C., 40-75° C., or 45-75° C. In some embodiments, the working fluids of the present invention may have a boiling point during operation of greater than 40° C., or greater than 50° C., or greater than 60° C., greater than 70° C., or greater than 75° C.

In some embodiments, the working fluids of the present disclosure may have dielectric constants that are less than 4.0, less than 3.2, less than 2.3, less than 2.2, less than 2.1, less than 2.0, or less than 1.9, as measured in accordance with ASTM D150 at room temperature.

In some embodiments, the working fluids of the present disclosure may be hydrophobic, relatively chemically unreactive, and thermally stable. The working fluids may have a low environmental impact. In this regard, the working fluids of the present disclosure may have a zero, or near zero, ozone depletion potential (ODP) and a global warming potential (GWP, 100 yr ITH) of less than 500, 300, 200, 100 or less than 10.

In some embodiments, the present disclosure may be directed to methods for cooling electronic components. Generally, the methods may include at least partially immersing a heat generating component (e.g., a computer server) in the above discussed working fluid. The method may further include transferring heat from the heat generating component using the above-described working fluid. The method may further include operating any of the above described adsorber assemblies to (i) receive a fluid stream from the interior space, the fluid stream comprising a vapor phase of the working fluid and a non-condensable gas; (ii) at least partially separate (and up to completely separate) the working fluid from the fluid stream and, then, vent the fluid stream to the environment external to the system; and (iii) return the separated working fluid to the interior space.

### Listing of Embodiments

1. A thermal management system comprising:
a housing having an interior space;
a heat-generating component disposed within the interior space;
a working fluid disposed within the interior space such that the heat-generating component contacts a liquid phase of the working fluid; and
an adsorber assembly disposed within the interior space, the adsorber assembly being in fluid communication with the interior space and an environment external to the thermal management system, and the adsorber assembly being configured to:
(i) receive a fluid stream from the interior space, the fluid stream comprising a vapor phase of the working fluid and a non-condensable gas;
(ii) at least partially separate the working fluid from the fluid stream and, then, vent the fluid stream to the environment external to the fluid space; and
(iii) return the separated working fluid to the interior space.
   2. The thermal management system of embodiment 1, wherein the adsorber assembly comprises an adsorption filter assembly comprising an inlet, an outlet, and an adsorption filter.
   3. The thermal management system of any one of the previous embodiments, wherein the adsorber assembly comprises a desorption mechanism configured to initiate desorption of the working fluid from the adsorption filter.
   4. The thermal management system of embodiment 3, wherein the desorption mechanism comprises a heating element.
   5. The thermal management system of embodiment 4, wherein the heating element comprises an electrical resistance heater.
   6. The thermal management system of embodiment 4, wherein the heating element comprises a source of electrical current that is configured to pass the current through a filter media of the adsorption filter.
   7. The thermal management system of embodiment 3, wherein the desorption mechanism comprises a vacuum device that is operably coupled to the adsorbent filter.
   8. The thermal management system of any one of the previous embodiments, wherein the
   vent assembly comprises a second adsorption filter assembly comprising a second inlet, a second outlet, and a second adsorption filter.
   9. The thermal management system of any one of the previous embodiments, wherein the
   vent assembly comprises a valve mechanism configured to route the fluid stream to the adsorption filter
   10. The thermal management system of any one of the previous embodiments, wherein the cooling system is configured such that in a steady state operating condition, (i) a liquid phase of the working fluid is disposed in a lower volume of the housing, (ii) a vapor phase of the working fluid is disposed above liquid phase, and (iii) a headspace phase comprising a non-condensable gas, water vapor, and working fluid vapor is disposed above the vapor phase.
   11. The thermal management system of embodiment 10, wherein the fluid stream comprises the head space phase.
   12. The thermal management system of any one of the previous embodiments, wherein the working fluid comprises a fluorinated material.
   13. The thermal management system of any one of the previous embodiments, wherein the working fluid has a boiling point at 1 atm of between 30 and 75° C.
   14. The thermal management system of any one of the previous embodiments, wherein the working fluid has a dielectric constant less than 2.5.
   15. The thermal management system of any one of the previous embodiments, wherein the heat-generating component comprises an electronic device.
   16. The thermal management system of embodiment 15, wherein the electronic device comprises a computing server.
   17. The thermal management system of embodiment 16, wherein the computing server operates at frequency of greater than 3 GHz.
   18. The thermal management system of any one of the previous embodiments, wherein the thermal management system further comprises a heat exchanger disposed within the system such that upon vaporization of the working fluid liquid, the vapor phase contacts the heat exchanger.

The operation of the present disclosure will be further described with regard to the following detailed examples. These examples are offered to further illustrate various embodiments and techniques. It should be understood, however, that many variations and modifications may be made while remaining within the scope of the present disclosure.

### EXAMPLES

Although specific embodiments have been illustrated and described herein for purposes of description of some embodiments, it will be appreciated by those of ordinary skill in the art that a wide variety of alternate and/or equivalent implementations may be substituted for the specific embodiments shown and described without departing from the scope of the present disclosure.

What is claimed is:

1. A thermal management system comprising:
a housing having an interior space;
a heat-generating component disposed within the interior space;
a working fluid disposed within the interior space such that the heat-generating component contacts a liquid phase of the working fluid; and
an adsorber assembly disposed within the interior space, the adsorber assembly being in fluid communication with the interior space and an environment external to the thermal management system, and the adsorber assembly being configured to:
(i) receive a fluid stream from the interior space, the fluid stream comprising a vapor phase of the working fluid and a non-condensable gas;
(ii) at least partially separate the working fluid from the fluid stream and, then, vent the fluid stream to the environment external to the fluid space; and
(iii) return the separated working fluid to the interior space.

2. The thermal management system of claim 1, wherein the adsorber assembly comprises an adsorption filter assembly comprising an inlet, an outlet, and an adsorption filter.

3. The thermal management system of claim 1, wherein the adsorber assembly comprises a desorption mechanism configured to initiate desorption of the working fluid from the adsorption filter.

4. The thermal management system of claim 3, wherein the desorption mechanism comprises a heating element.

5. The thermal management system of claim 4, wherein the heating element comprises an electrical resistance heater.

6. The thermal management system of claim 4, wherein the heating element comprises a source of electrical current that is configured to pass the current through a filter media of the adsorption filter.

7. The thermal management system of claim 3, wherein the desorption mechanism comprises a vacuum device that is operably coupled to the adsorbent filter.

8. The thermal management system of claim 1, wherein the vent assembly comprises a second adsorption filter assembly comprising a second inlet, a second outlet, and a second adsorption filter.

9. The thermal management system of claim 1, wherein the vent assembly comprises a valve mechanism configured to route the fluid stream to the adsorption filter

10. The thermal management system of claim 1, wherein the cooling system is configured such that in a steady state operating condition, (i) a liquid phase of the working fluid is disposed in a lower volume of the housing, (ii) a vapor phase of the working fluid is disposed above liquid phase, and (iii) a headspace phase comprising a non-condensable gas, water vapor, and working fluid vapor is disposed above the vapor phase.

11. The thermal management system of claim 10, wherein the fluid stream comprises the head space phase.

12. The thermal management system of claim 1, wherein the working fluid comprises a fluorinated material.

13. The thermal management system of claim 1, wherein the working fluid has a boiling point at 1 atm of between 30 and 75° C.

14. The thermal management system of claim 1, wherein the working fluid has a dielectric constant less than 2.5.

15. The thermal management system of claim 1, wherein the heat-generating component comprises an electronic device.

16. The thermal management system of claim 15, wherein the electronic device comprises a computing server.

17. The thermal management system of claim 16, wherein the computing server operates at frequency of greater than 3 GHz.

18. The thermal management system of claim 1, wherein the thermal management system further comprises a heat exchanger disposed within the system such that upon vaporization of the working fluid liquid, the vapor phase contacts the heat exchanger.
